(19) United States
(12) Patent Application Publication
(10) Pub. No.: US 2025/0199287 A1
(43) Pub. Date: Jun. 19, 2025

(54) MICROSCOPE OBJECTIVE ADAPTER FOR TESTING SEMICONDUCTORS AND THIN FILM MATERIALS

(71) Applicant: Xallent Inc., Albany, NY (US)

(72) Inventors: Kwame Amponsah, Latham, NY (US); Mehmet Ozdogan, Ithaca, NY (US); Pardeep Kumar, Ithaca, NY (US); Clive A. D'souza, Ithaca, NY (US)

(73) Assignee: Xallent Inc., Albany, NY (US)

(21) Appl. No.: 18/852,205

(22) PCT Filed: Feb. 22, 2023
(86) PCT No.: PCT/US2023/063040

§ 371 Date: Sep. 27, 2024

Related U.S. Application Data
(60) Provisional application No. 63/362,095, filed on Mar. 29, 2022.

(51) Int. Cl. G02B 21/26; G01R 31/28; G02B 21/32

(52) U.S. Cl. CPC G02B 21/26; G01R 31/2887; G02B 21/32

(57) ABSTRACT

An objective adapter comprising of a frame, a frame cover, an opening to insert an objective, and a platen is provided. A manipulator that houses a probe chip is placed on the platen. The probe chip is used to perform electrical, mechanical, optical, chemical, and structural measurements of thin film materials and semiconductors. The objective adapter mounts onto microscopes, including 3rd party microscopes.

### CROSS-REFERENCE TO RELATED APPLICATIONS

This application claims priority to U.S. Provisional Patent Application Ser. No. 63/362,095, filed on Mar. 29, 2022, which application is hereby incorporated by reference in its entirety.

### FIELD OF THE INVENTION

The present disclosure is directed generally to a microscope objective adapter for testing semiconductors and thin film materials.

### BACKGROUND

Optical microscopes, electron microscopes, and scanning probe microscopes are used to observe the structure and topography of samples. These microscopes are routinely adapted with various modalities such as electron-dispersive X-ray spectroscopy systems, atomic force microscope adapters, nanoprobing systems, and many more. These adaptations allow for correlative measurements as well as increases the value and cost of test of these microscopes.

### SUMMARY OF THE INVENTION

The present disclosure is directed generally towards an objective adapter for testing samples of semiconductors and thin film materials. The objective adapter attaches to an objective, and the objective is connected to a microscope to enable observation of a sample. A manipulator could be placed on a platen of the objective adapter. A probe head may be integrated with the manipulator. Thus, the objective adapter and the manipulator may be used to position the probe head to probe the sample with a probe tip, while both the sample and the probe tip are under observation via the objective. Probing the sample may enable a wide variety of measurements, such as electrical, mechanical, optical, chemical, and structural measurements of thin film materials and semiconductors.

According to an aspect, is an objective adapter is provided. The objective adapter comprises at least a frame, a frame cover, an opening to insert an objective, and at least a platen.

According to an aspect, the platen is made of a material that attracts a magnet or a magnetic material.

According to an aspect, the platen is made of a non-magnetic material.

According to an aspect, the non-magnetic material of the platen is steel, nickel, cobalt, neodymium or a combination thereof.

According to an aspect, a magnet is embedded into the platen.

According to an aspect, the platen is made from materials such as plastic, ceramic, Acrylonitrile butadiene styrene (ABS), Polylactic acid (PLA) or a combination thereof.

According to an aspect, a manipulator is arranged on top of the platen.

According to an aspect, a base of the manipulator is magnetic.

According to an aspect, a base of the manipulator is vacuum operated.

According to an aspect, the manipulator comprises at least a linear stage, or at least a rotational stage, or at least a tilt stage, or a combination thereof.

According to an aspect, a probe head is integrated with the manipulator.

According to an aspect, a probe board is inserted into the probe head.

According to an aspect, a probe chip is attached to the probe board.

According to an aspect, the probe chip comprises of at least a probe tip.

According to an aspect, wherein the frame and the frame cover are fused together to form a fused frame.

According to an aspect, an objective is inserted into the fused frame.

According to an aspect, an objective is inserted between the frame and the frame cover.

According to an aspect, the objective is directly connected to the microscope.

According to an aspect, the objective is connected to an objective connector.

According to an aspect, the objective connector is connected to a microscope.

According to an aspect, a dovetail is connected to a first end of the objective connector, and a second end of the objective connector directly connects to a microscope.

According to an aspect, one end of the objective is connected to a dovetail.

According to an aspect, the dovetail on the objective is connected to a dovetail portion of an objective connector.

According to an aspect, a magnet or a magnetic material is connected to a first end of the objective connector and a second end of the objective connector directly connects to a microscope.

According to an aspect, one end of the objective is connected to a magnet or magnetic material.

According to an aspect, the magnet or the magnetic material connected to the first end of the objective connector is attracted to a second magnetic or a second magnetic material connected to one end of the objective.

According to an aspect, wherein a second magnet or a second magnetic material connected to a one end of the objective is attracted to the magnet or the magnetic material connected to the first end of the objective connector.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

These and other aspects of the invention will be apparent from the embodiments described below.

### BRIEF DESCRIPTION OF THE DRAWINGS

The present invention will be more fully understood and appreciated by reading the following Detailed Description in conjunction with the accompanying drawings, in which:

FIG. 1 is a perspective view of a microscope that is integrated with the objective adapter according to the present disclosure.

FIG. 2A is an expanded view of an objective adapter according to the present disclosure.

FIG. 2B is a perspective view of an objective adapter according to the present disclosure.

FIG. 3 is a perspective view of the objective adapter that is connected to an objective and a manipulator placed on the adapter according to the present disclosure.

FIG. 4A is a perspective view of a manipulator according to the present disclosure.

FIG. 4B is a perspective view of a manipulator according to the present disclosure.

FIG. 4C is a perspective view of a probe board with a probe chip according to the present disclosure.

FIG. 4D is a perspective view of a probe chip according to the present disclosure.

FIG. 4E is a perspective view of probe tips according to the present disclosure.

FIG. 5A is an expanded view of a manipulator according to the present disclosure.

FIG. 5B is an expanded view of a manipulator according to the present disclosure.

FIG. 6A is a perspective view of the manipulator that is placed on the objective adapter according to the present disclosure.

FIG. 6B is a perspective view of the manipulator that is placed on the objective adapter according to the present disclosure.

FIG. 7A is a perspective view of a microscope that is integrated with the objective adapter according to the present disclosure.

FIG. 7B is a perspective view of a microscope that is integrated with the objective adapter according to the present disclosure.

FIG. 8A is a perspective view of an objective adapter with multiple platens according to the present disclosure.

FIG. 8B is a perspective view of an objective adapter with multiple platens according to the present disclosure.

FIG. 8C is a perspective view of an objective adapter that is integrated with the objective and multiple manipulators according to the present disclosure.

FIG. 8D is a perspective view of a microscope that is integrated with the objective adapter and multiple manipulators according to the present disclosure.

FIG. 9A is a perspective view of an objective that is connected to a dovetail according to the present disclosure.

FIG. 9B is a perspective view of an objective connector that is connected to a dovetail according to the present disclosure.

FIG. 9C is a perspective view of an objective connector that is connected to an objective according to the present disclosure.

FIG. 9D is a perspective view of a microscope that is integrated with the objective adapter according to the present disclosure.

### DETAILED DESCRIPTION OF EMBODIMENTS

The present disclosure describes various embodiments of an objective adapter for testing samples of semiconductors and thin film materials. The objective adapter enables detailed study of electrical, mechanical, optical, and chemical responses of semiconductors and thin film materials by positioning a probe chip to contact a sample while the sample is observed by an objective of a microscope.

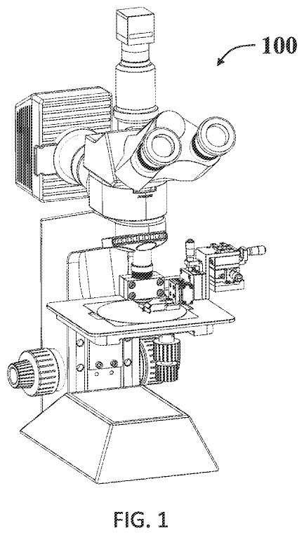

FIG. 1 illustrates a perspective view of a microscope 100 integrated with the objective adapter according to the present disclosure.

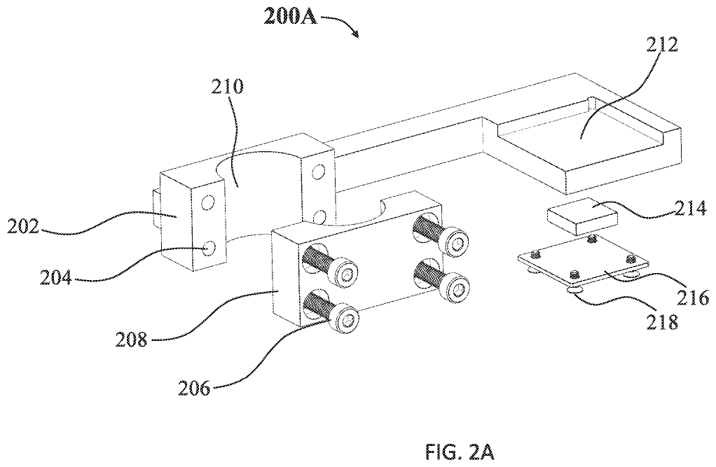

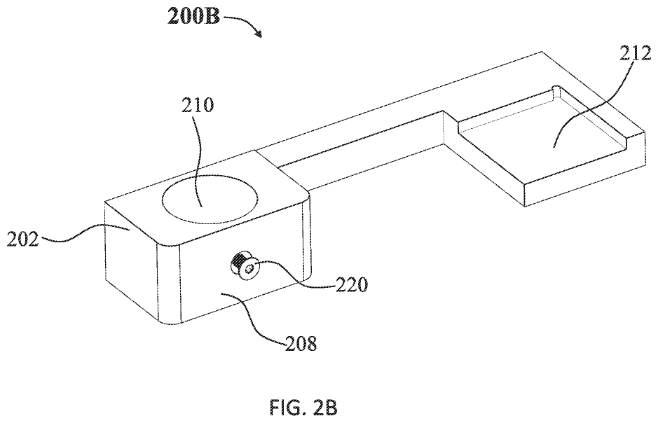

FIG. 2A illustrates an objective adapter 200A. The frame 202 has holes 204 that accepts screws 206. A frame cover 208 has holes that accepts screws 206. The screws 206 ensure that the cover 208 is securely connected to the frame 202. There is an opening 210 where the objective is inserted. The platen 212 is where a manipulator may be placed. The platen 212 could be made of a magnetic material or a non-magnetic material. In the case where the platen 212 is made of a non-magnetic material such as plastic, a magnet 214 is embedded in the platen 212. The magnet 214 helps to attract a manipulator with a magnetic base. The magnet 214 is affixed to the platen 212 and the magnet cover 216 is secured to the platen 212 with screws 218.

Referring to FIG. 2A, in another embodiment, the platen 212 is embedded with a magnet 214. The magnet 214 could be inside, on top, or at the bottom of the platen 212.

Referring to FIG. 2A, in another embodiment, the entire frame 202 and platen 212 are made of a material that attracts a magnet or a magnetic material. Examples of such materials are steel, nickel, cobalt, neodymium or a combination thereof.

Referring to FIG. 2A, in another embodiment, the entire frame 202 and platen 212 are made of a material that does not attract a magnet (non-magnetic material). Examples of such materials are plastics, ceramics, Acrylonitrile butadiene styrene (ABS), Polylactic acid (PLA) or a combination thereof.

FIG. 2B, in another embodiment, is an objective adapter 200B. The frame 202 and frame cover 208 are fused or integrated as a single piece. The fused frame has opening 210. The opening 210 is designed and manufactured to tightly fit an objective. Furthermore, screw 220 could be inserted into the fused frame to push against the objective to firmly secure the objective to the fused frame.

Referring to FIG. 2A and FIG. 2B, the objective adapter 200A and 200B could be made using Computer Numerical Control (CNC) machining, 3D printing, moldering, etc.

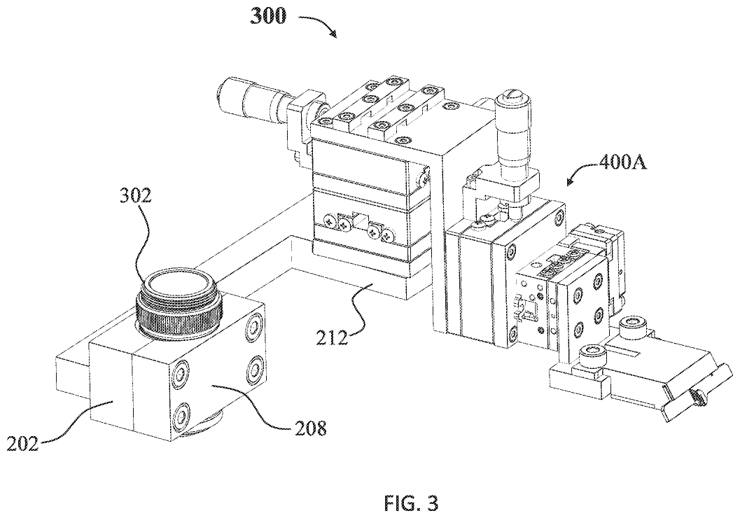

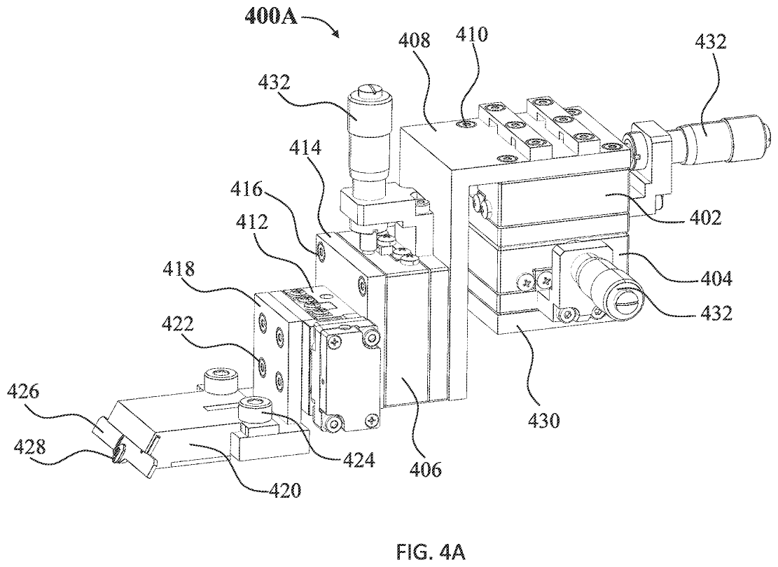

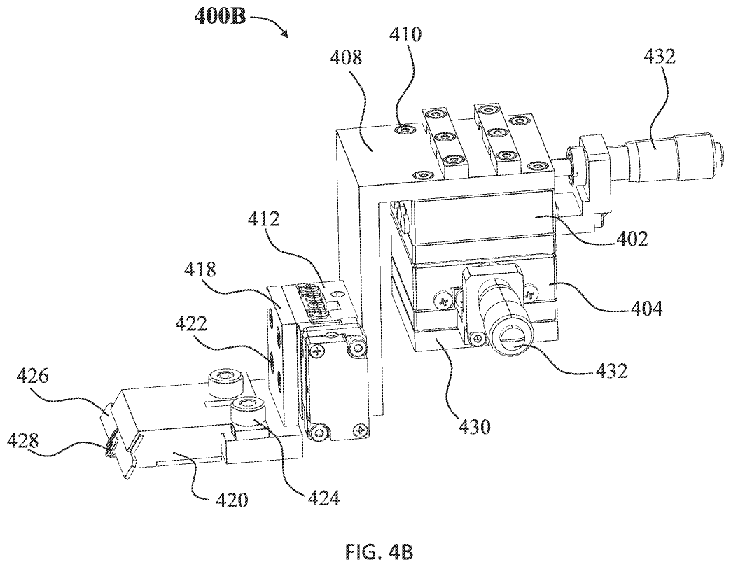

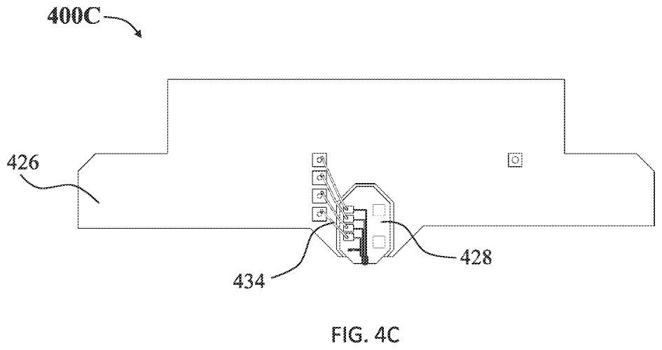

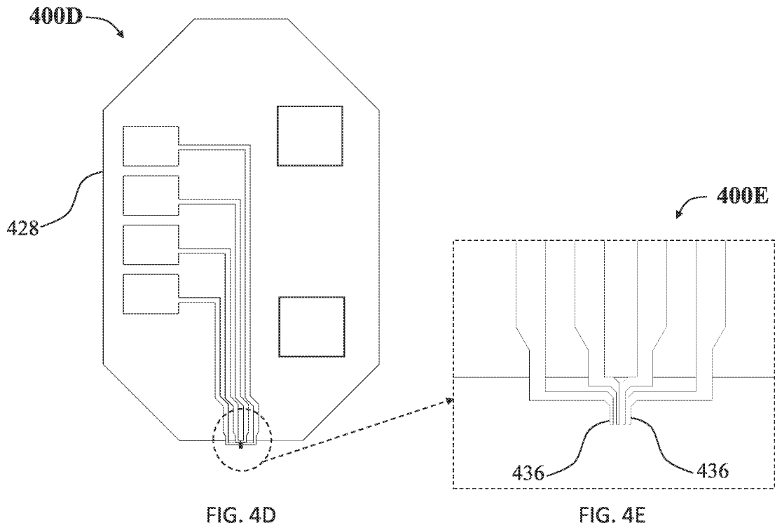

FIG. 3 illustrates a perspective view of the objective adapter 200A, where an objective 302 is inserted into the opening 210. A manipulator 400A with a magnetic base is placed on the platen 212. In some examples, the manipular 400A is used to position a probe chip 428 (see FIG. 4A) relative to a sample under observation by the objective 302. In some examples, the manipulator 400A brings the probe chip 428 into contact with the sample.

Referring to FIG. 3, in another embodiment, the objective adapter 200A could be connected to the objective of a scanning electron microscope, scanning transmission electroscope, scanning laser microscope, and optical microscope.

Referring to FIG. 3, in another embodiment, the objective adapter 200A could be connected to an atomic force microscope or a scanning tunneling microscope.

Referring to FIG. 3, details about the manipulator 400A can be found in Internal Patent Application No. PCT/US22/72768 (claiming priority to U.S. Provisional Patent Application No. 63/202,548), the entirety of which is incorporated by reference herein.

FIG. 4A illustrates a perspective view of the manipulator 400A. The manipulator 400A comprises of an X (402), Y (404), and Z (406) linear stages. The linear stages 402, 404, 406 could be manually, semi-automatically, or automatically operated. The linear stages 402, 404, 406 could be piezoelectric, or motor driven or a combination thereof. The X-stage 402 is mounted above the Y-stage 404 using screws. An L-bracket 408 connects to the top of the X-stage 402 using screws 410. The Z-stage 406 is connected to the L-bracket 408. In certain applications, an additional Z-stage (412) could be connected to the Z-stage 406. Z-stage 412 could provide incremental motion ranging from attometers to micrometers or millimeters. Z-stage 412 could be a piezoelectric stage. Plate 414 serves as the interface between the Z-stage 406 and Z-stage 412. Plate 414 is screwed into Z-stage 406 using screws 416, and Z stage 412 is screwed into plate 414.

Referring to FIG. 4A, an L-bracket 418 connects the probe head 420 to the Z stage 412. The L-bracket 418 is connected to the Z stage 412 with screws 422. Screws 424 connect the probe head 420 to the L-bracket 418.

Referring to FIG. 4A, a probe board 426 is inserted into the probe head 420. The probe board 426 houses a probe chip 428. The probe chip 428 comprises of a single probe tip or an array of monolithically integrated probe tips. The probe chip 428 may be used to perform a wide array of measurements by contacting the sample, such as electrical, mechanical, optical, chemical, and structural measurements.

Referring to FIG. 4A, the Y-stage 404 is connected to a base plate 430 and a micro-verniers 432 could be used to manually move the X (402), Y (404), and Z (406) stages.

FIG. 4B, in accordance with an embodiment, illustrates a perspective view of a manipulator 400B. The manipular 400B of FIG. 4B is a variation of the manipulator 400A of FIG. 4A with the Z-stage 406 removed from the overall manipulator assembly. As shown in FIG. 4B, the Z-stage 412 of the manipulator 400B connects directly to the L-bracket 408.

Referring to FIG. 4A and FIG. 4B, the linear stages 402, 404, 406 may be configured to be positionally interchangeable. As an example, an X-stage 402 could be used as a Y-stage 404 and vice versa.

Referring to FIG. 4A and FIG. 4B, in another embodiment, along with the X (402), Y (404), Z (406) linear stages, rotational and/or tilt stages could also be integrated with the manipulator 400A and 400B.

FIG. 4C, in accordance with an embodiment, illustrates the probe chip 428 connected to the probe board 426. Wire bonds 434 may be used to electrically connect the probe chip 428 to the probe board 426. Alternatively, flip chip bonding could be used to electrically connect the probe chip 428 to the probe board 426. The probe board 426 could be a printed circuit board.

FIG. 4D, in accordance with an embodiment, illustrates the probe chip 428. The probe chip comprises of one or more probe tips 436 as shown in the expanded view in FIG. 4E. Details of the probe chip 428 can be found in Internal Patent Application No. PCT/US22/72768 (claiming priority to U.S. Provisional Patent Application No. 63/202,548), the entirety of which is incorporated by reference herein.

Referring to FIG. 4A and FIG. 4B, in another embodiment, the X (402), Y (404), and Z (406) stages could be integrated into a single scanner. The stages 402, 404, 406 and scanner could be made of piezoelectric or motor drive. The scanner could be operated in open or closed loop. The scanner is like those used on scanning probe microscopes such as atomic force microscopes and scanning tunneling microscopes.

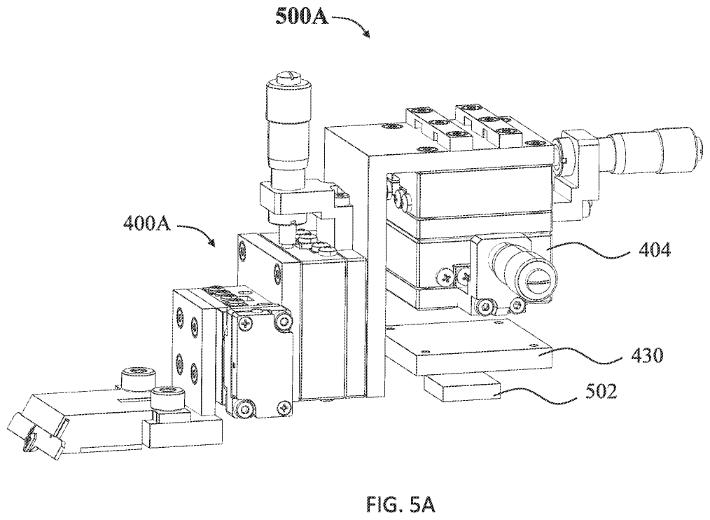

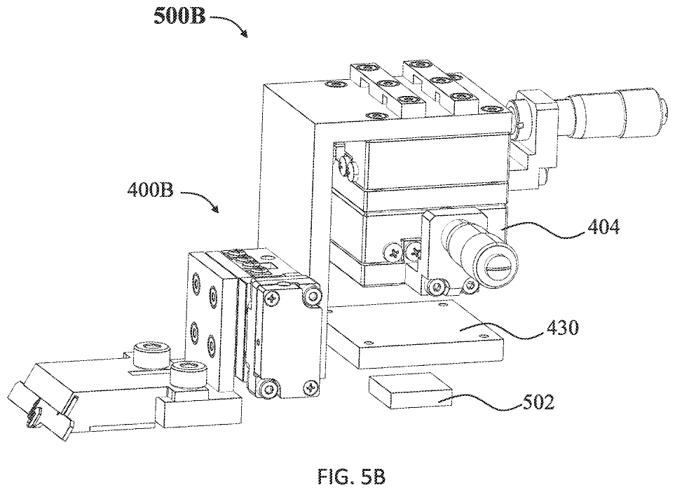

FIG. 5A illustrates an expanded version of the manipulator 400A of FIG. 4A. A magnet 502 is affixed to the base plate 430. The base plate 430 is affixed to the bottom of the Y-stage 404. Screws (not shown) could be used to affix the base plate 430 to the bottom of the Y-stage 404.

FIG. 5B illustrates an expanded version of the manipulator 400B of FIG. 4B. A magnet 502 is affixed to the base plate 430. The base plate 430 is affixed to the bottom of the Y stage 404. Screws (not shown) could be used to affix the base plate 430 to the bottom of the Y stage 404.

Referring to FIG. 5A and FIG. 5B, the base plate 430 could be made from a material that attracts a magnet or a magnetic material. In that case, there is no need for magnet 502.

Referring to FIG. 5A and FIG. 5B, the manipulator 400A and 400B could have a vacuum operated base plate 430. In such an embodiment, there is no need for magnet 502. When the vacuum is turned on, the manipulator 400A and 400B could firmly sit on the platen 212 of the objective adapter.

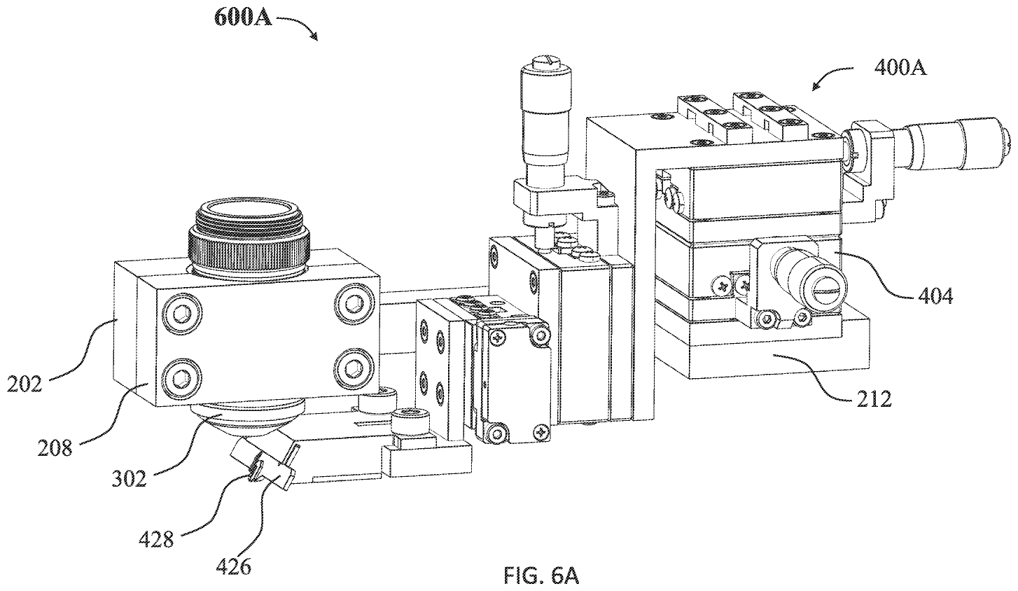

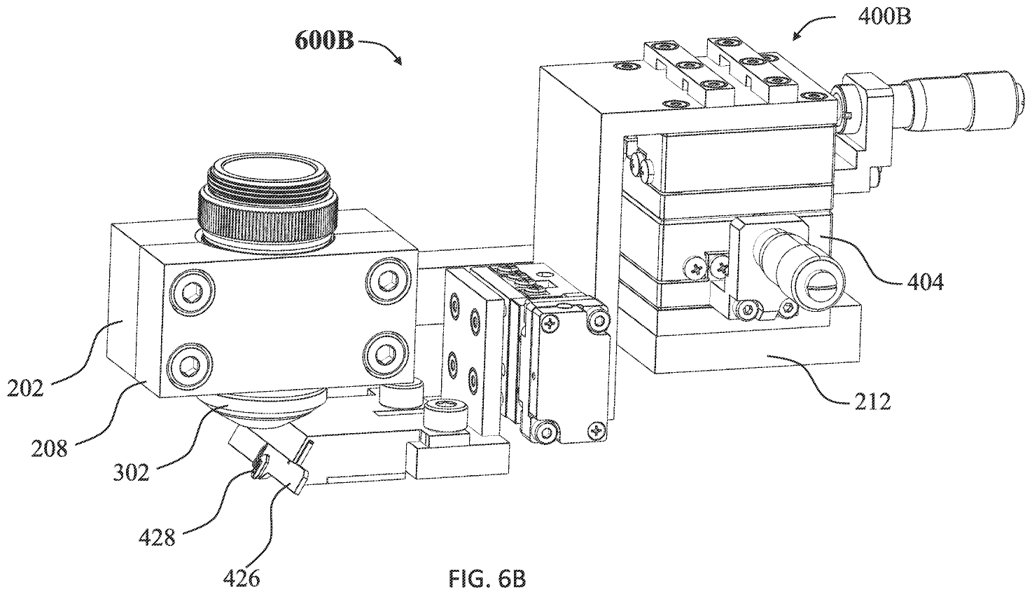

In FIG. 6A and FIG. 6B, the manipulators 400A and 400B are placed on the platen 212 of an objective adapter 600A, 600B respectively. An objective 302 is inserted into the objective adapter 600A, 600B to view the probe tips 436 (not shown) on the probe chip 428.

Referring to FIG. 6A and FIG. 6B, in another embodiment, the linear Y-stage 404 could be affix or screwed into the platen 212 making the entire manipulator 400A and 400B non-rotatable.

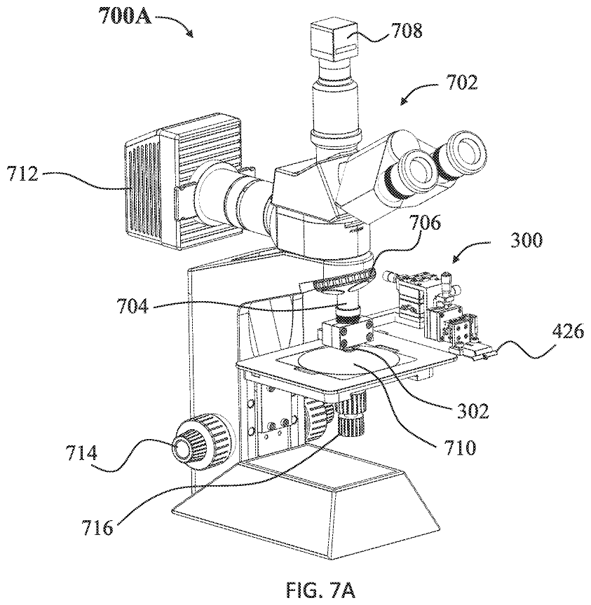

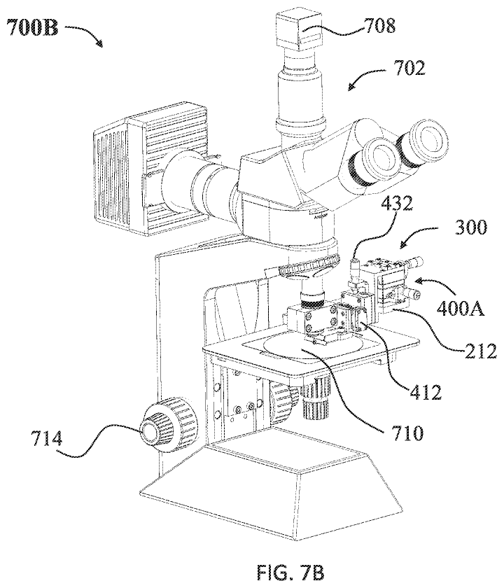

FIG. 7A, in accordance with an embodiment, a microscope 702 is integrated with the objective adapter 300. An objective connector 704 facilitates the connection of the objective 302 to the microscope 702 or a turret 706 of the microscope 702. The objective connector 704 could be custom designed to mount to existing 3^{rd} party microscopes and turrets. The manipulator 400A is rotated away from the objective 302 during the mounting and dismounting of a probe board 426. A camera 708 is used to capture a live image of the wafer 710 or device-under-test (DUT). The microscope 702 is equipped with a light source 712 to offer illumination to the DUT. The Z-knob 714 could be rotated to bring the DUT into and out of focus of the camera. The DUT could be translated using knob 716.

Referring to FIG. 7A, the objective connector 704 could be designed with one or more threads such that the objective 302 screws into it.

Referring to FIG. 7A, the objective connector 704 could be designed so that the objective 302 magnetically connects to it.

Referring to FIG. 7A, the objective connector 704 could be designed so that the objective 302 inserts into it. Both ends of the objective connector 704 and objective 302 would have a complementary dovetail to allow for insertion.

Referring to FIG. 7A, in another embodiment, the objective 302 is directly connected to the microscope 702 or the turret 706 without the need for the objective connector 704.

Referring to FIG. 7A, details of the microscope assembly can be found in Internal Patent Application No. PCT/US22/72768 (claiming priority to U.S. Provisional Patent Application No. 63/202,548), the entirety of which is incorporated by reference herein.

FIG. 7B, in accordance with an embodiment, a microscope 702 is integrated with the objective adapter 300. The manipulator 400A is rotated on the platen 212 to bring the probe tips 436 (not shown) below the objective 302. The probe tips 436 contact the DUT by performing the following: (1) turning the Z-knob 714 to bring the DUT up, or (2) using a software program to instruct the Z-stage 412 to bring the probe tips 436 down, or (3) turning the micro-verniers 432 to bring the tips down, or (4) performing any combination of the above.

Referring to FIG. 7B, the objective 302 along with the camera 708 can view the probe tips 436 and the DUT 710 simultaneously.

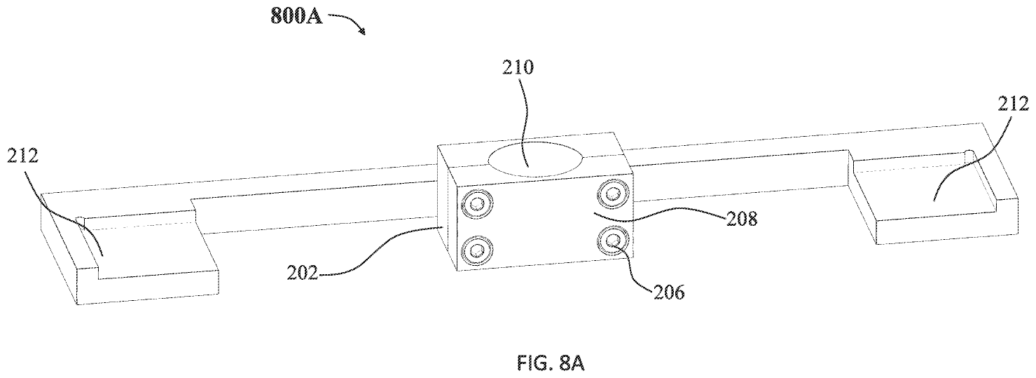

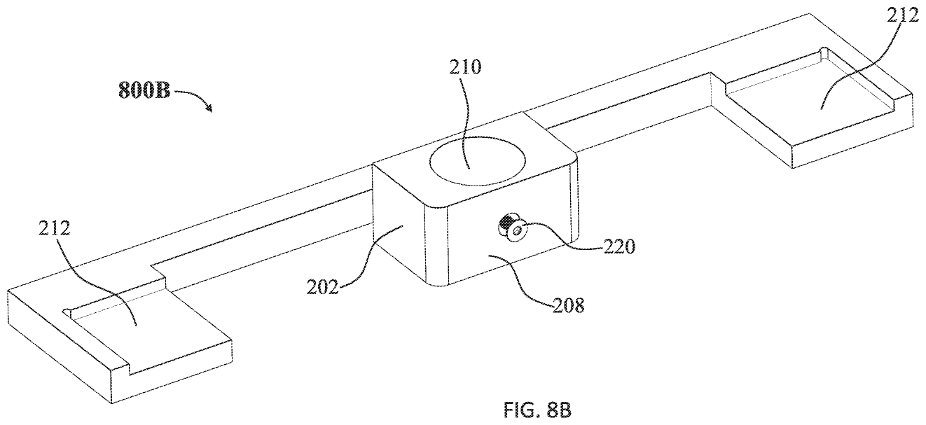

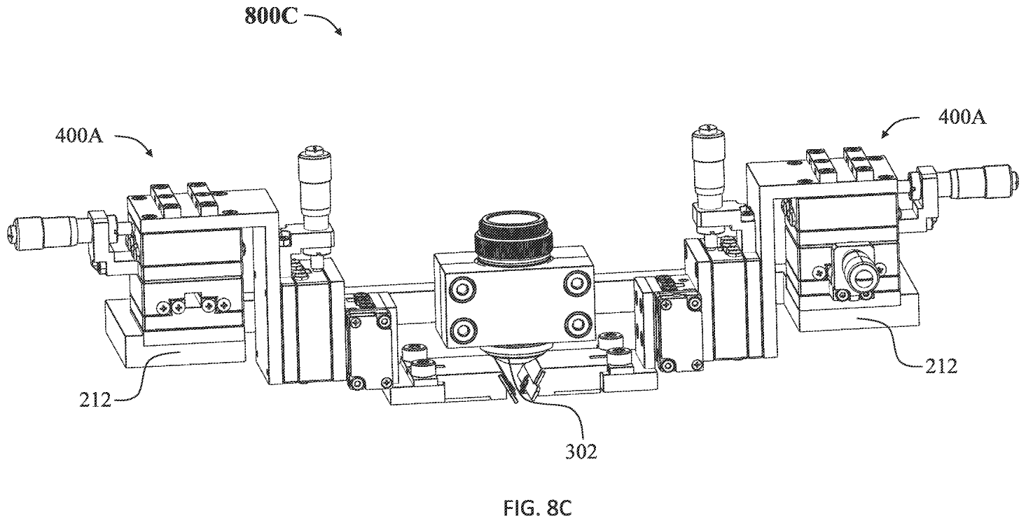

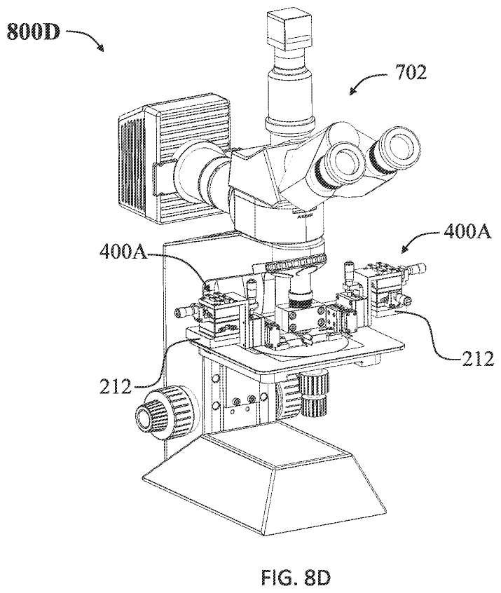

FIG. 8A, in accordance with an embodiment, an objective adapter 800A could be designed to have multiple platens 212.

FIG. 8B, in accordance with an embodiment, an objective adapter 800B could be designed to have multiple platen 212 and the frame 202 and frame cover 208 could be fused into a single piece.

FIG. 8C, in accordance with an embodiment, multiple manipulators 400A are placed on the platens 212 of an objective adapter 800C.

FIG. 8D, in accordance with an embodiment, a microscope 702 is integrated with the objective adapter 800C shown in FIG. 8C. Multiple manipulators 400A are placed on the platens 212 of the objective adapter 800C.

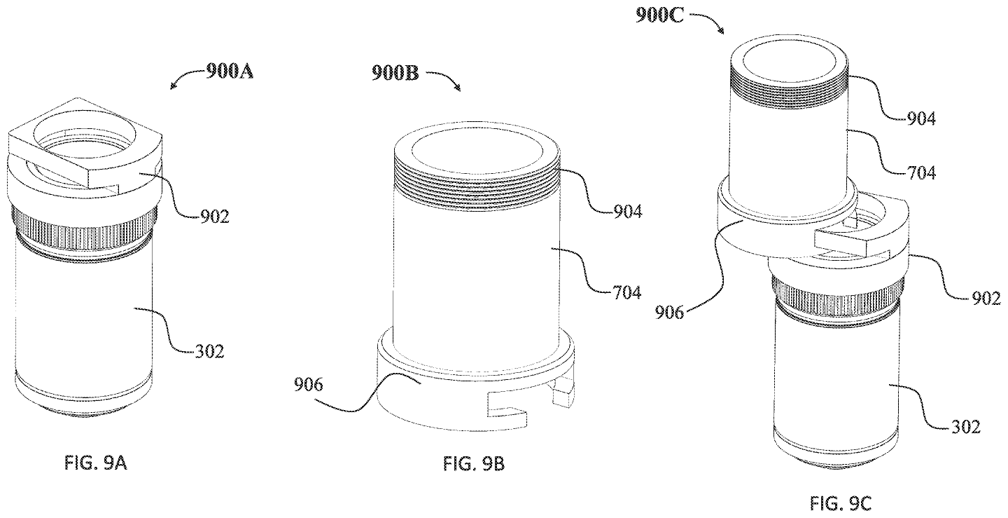

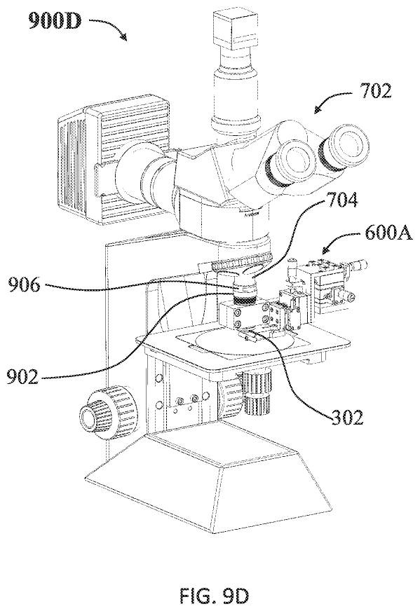

FIG. 9A, in accordance with an embodiment, is an objective 302 that is connected to a dovetail 902. The top section of the objective 302 could have threads that could screw into a threaded dovetail 902.

FIG. 9B, in accordance with an embodiment, is an objective connector 704. Both ends of the objective connector 704 could be threaded 904. A threaded dovetail 906 connects to one end of the objective connector 704 and the other end of the objective connector 704 could connect directly to the microscope 702 or the turret 706. The objective connector 704 and dovetail 906 could also be designed and manufactured as a single piece.

Referring to FIGS. 9A and 9B, the dovetails 902 and 906 could be replaced with magnetic materials that allow the objective 302 to magnetically connect to the objective connector 704.

FIG. 9C, in accordance with an embodiment, illustrates how the dovetails 902 and 906 are inserted into each other.

FIG. 9D, in accordance with an embodiment, the microscope 702 is integrated with an objective adapter 600A. The dovetail 902 connected to the objective 302 is inserted into the dovetail 906 that is connected to the objective connector 704.

It should be noted that there are several ways of attaching the objective adapter to the objective and microscope. The attachment techniques described in this application do not serve to limit the integration of the objective adapter to microscopes.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements can optionally be present other than the elements specifically identified by the “and/or” clause, whether related or unrelated to those elements specifically identified.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.”

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements can optionally be present other than the elements specifically identified within the list of elements to which the phrase “at least one” refers, whether related or unrelated to those elements specifically identified.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

While various examples have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the examples described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings is/are used. Those skilled in the art will recognize or be able to ascertain using no more than routine experimentation, many equivalents to the specific examples described herein. It is, therefore, to be understood that the foregoing examples are presented by way of example only and that, within the scope of the appended claims and equivalents thereto, examples can be practiced otherwise than as specifically described and claimed. Examples of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present disclosure.

What is claimed is:

1. An objective adapter, the objective adapter comprising:
at least a frame;
a frame cover;
an opening to insert an objective;
and at least a platen.

2. The objective adapter of claim 1, wherein the platen is made of a material that attracts a magnet or magnetic material.

3. The objective adapter of claim 2, wherein the material of the platen is steel, nickel, cobalt, neodymium, or a combination thereof.

4. The objective adapter of claim 1, wherein the platen is made of non-magnetic material.

5. The objective adapter of claim 4, wherein a magnet is embedded into the platen.

6. The objective adapter of claim 4, wherein the non-magnetic material of the platen is a plastic, a ceramic, Acrylonitrile butadiene styrene (ABS), Polylactic acid (PLA) or a combination thereof.

7. The objective adapter of claim 1, wherein a manipulator is arranged on top of the platen.

8. The objective adapter of claim 7, wherein a base of the manipulator is magnetic.

9. The objective adapter of claim 7, wherein a base of the manipulator is vacuum operated.

10. The objective adapter of claim 7, wherein the manipulator comprises at least a linear stage, or at least a rotational stage, or at least a tilt stage, or a combination thereof.

11. The objective adapter of claim 7, wherein a probe head is integrated with the manipulator.

12. The objective adapter of claim 11, wherein a probe board is inserted into the probe head.

13. The objective adapter of claim 12, wherein a probe chip is attached to the probe board.

14. The objective adapter of claim 13, wherein the probe chip comprises at least a probe tip.

15. The objective adapter of claim 1, wherein the frame and the frame cover are fused together to form a fused frame.

16. The objective adapter of claim 15, wherein an objective is inserted into the fused frame.

17. The objective adapter of claim 1, wherein an objective is inserted between the frame and the frame cover.

18. The objective adapter of claim 17, wherein the objective is directly connected to a microscope.

19. The objective adapter of claim 17, wherein the objective is connected to an objective connector.

20. The objective adapter of claim 19, wherein the objective connector is connected to a microscope.

21. The objective adapter of claim 19, wherein a dovetail is connected to a first end of the objective connector, and wherein a second end of the objective connector directly connects to a microscope.

22. The objective adapter of claim 17, wherein one end of the objective is connected to a dovetail.

23. The objective adapter of claim 22, wherein the dovetail is connected to a dovetail portion of an objective connector.

24. The objective adapter of claim 19, wherein a magnet or a magnetic material is connected to a first end of the objective connector and a second end of the objective connector directly connects to a microscope.

25. The objective adapter of claim 17, wherein one end of the objective is connected to a magnet or magnetic material.

26. The objective adapter of claim 24, wherein the magnet or the magnetic material connected to the first end of the objective connector is attracted to a second magnetic or a second magnetic material connected to one end of the objective.

27. The objective adapter of claim 24, wherein a second magnet or a second magnetic material connected to a one end of the objective is attracted to the magnet or the magnetic material connected to the first end of the objective connector.
